(19) United States
(12) Patent Application Publication
(10) Pub. No.: US 2026/0372154 A1
(43) Pub. Date: Nov. 19, 2026

(54) FLUX DIPPING DEVICE AND METHOD

(71) Applicant: STATS ChipPAC Management Pte. Ltd., Singapore (SG)

(72) Inventors: JongChan PARK, Incheon (KR); HyungSuk MIN, Incheon (KR)

(21) Appl. No.: 19/679,750

(22) Filed: May 17, 2026

(30) Foreign Application Priority Data
May 19, 2025 (CN) 202510644126.0

(51) Int. Cl. H10W 72/00

(52) U.S. Cl. CPC H10W 72/07131; H10W 72/0112; H10W 72/01215; H10W 72/07173

(57) ABSTRACT

A flux dipping device is provided. The flux dipping device comprises: a rack, a tray mounted on the rack and configured to hold flux; and a damper mounted between the rack and the tray, and configured to damp a downward movement of the tray when the tray is compressed downward against the rack.

### TECHNICAL FIELD

The present application generally relates to semiconductor technology, and more particularly, to a flux dipping device and method.

### BACKGROUND OF THE INVENTION

Laser compression bonding (LCB) or soldering processes have been used to replace conventional massive reflowing processes in forming semiconductor packages, because during the laser compression soldering process thermal stresses within semiconductor packages can be reduced. Furthermore, before the soldering process, flux can be applied to the soldering material dispensed on the electronic components to be mounted on packages substrate of the semiconductor packages, which can help the subsequent reflowing of the soldering material. However, it is noted that the efficiency of the flux dipping process is low, which may further lead to a decrease in UPH (Units Per Hour) for the manufacturing of semiconductor packages.

Therefore, a need exists for further improvement of conventional flux dipping devices.

### SUMMARY OF THE INVENTION

An objective of the present application is to provide a flux dipping device with an improved efficiency.

According to an aspect of the present application, a flux dipping device is provided. The flux dipping device comprises: a rack, a tray mounted on the rack and configured to hold flux; and a damper mounted between the rack and the tray, and configured to damp a downward movement of the tray when the tray is compressed downward against the rack.

According to another aspect of the present application, a method for flux dipping is provided. The method comprises: providing a tray holding flux mounted on a rack via a damper; moving downward towards the tray a dipping head holding an electronic component with a soldering material dispensed at its bottom side; compressing by the dipping head the tray against the rack via the damper to dip the soldering material with the flux in the tray; and moving the dipping head away from the tray.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 illustrates a flux dipping method.

FIG. 2 illustrates a flux dipping method according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, before a reflowing process implemented by a laser compression bonding tool, a soldering material the in form of solder bumps mounted on an electronic component needs to be dipped with flux. For example, the electronic component may be held by a compression head and be moved closer to a flux tray where the solder bumps can be brought into contact with flux. However, it is noted that the efficiency of the dipping process is low, and solder bumps or even electronic components may be damaged in some cases. Furthermore, it is noted by the inventors of the present application that a deceleration action of the compression head during the dipping process is the main reason for the above disadvantages of conventional flux dipping processes.

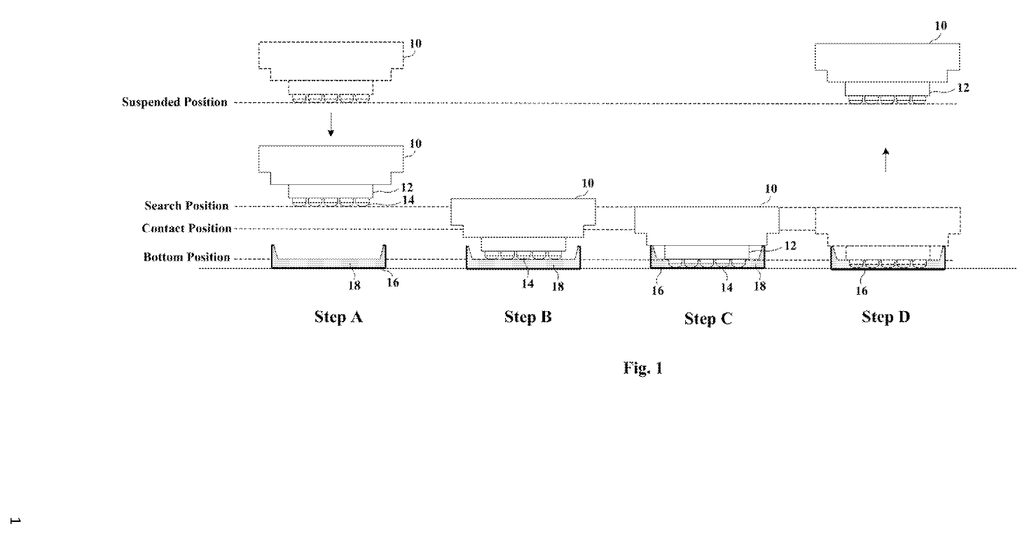

FIG. 1 illustrates a flux dipping method. As shown in Step A of FIG. 1, a dipping head 10 such as a compression head may be used to hold an electronic component 12 at its bottom side. The electronic component 12 may be a semiconductor die or a semiconductor package, and a soldering material such as solder bumps 14 may be formed at a bottom surface of the electronic component 12, which allows the electronic component 12 to be mounted onto a substrate (not shown) in a subsequent compression bonding process or other similar reflowing or soldering process. The dipping head 10 can move vertically the electronic component 12 towards or away from a tray 16 where flux 18 is held. The dipping head 10 is initially at a suspended position, and then, it can move to a search position which is closer to the tray 16 than the suspended position. After moving past the search position, the dipping head 10 may start to decelerate to avoid colliding into the flux 18 and the tray 16. For example, a speed of the dipping head 10 may decrease from 15 mm/s at or near the suspended position to 0.25 mm/s at the search position. However, 0.25 mm/s is still too fast for the dipping process, as discussed below in more details. As shown in Step B of FIG. 1, when the dipping head 10 moves further to a contact position where the solder bumps 14 underneath the electronic component 12 are in contact with the flux 18, the speed of the dipping head 10 may decrease further to 0.025 mm/s. As shown in FIG. 1C, in order to have a satisfactory amount of flux adhered onto the solder bumps 14, the dipping head 10 may move downward further until the solder bumps 14 are in contact with the tray 16, i.e., the dipping head 10 reaches a bottom position. At the bottom position, the speed of the dipping head 10 may decrease to zero or close to zero, for example, to 0.0004 mm/s. Afterwards, the dipping head 10 may be elevated from the bottom position back to the suspended position, as is shown in Step D of FIG. 1. It can be seen that the deceleration action of the dipping head from the suspended position shown in Step A of FIG. 1 to the bottom position shown in Step C of FIG. 1 needs to be accurately controlled, otherwise the dipping head 10 may have a speed which is fast enough to cause collision between the solder bumps 14 and the tray 16, which further results in damages to the solder bumps 14, the electronic component 12 and the tray 16. Usually, it may take 6 seconds or even longer to decelerate the dipping head 10 from 15 mm/s at the suspended position to 0.0004 mm/s at the bottom position and back to the suspended position, which significantly affects the efficiency of the flux dipping process.

In order to address the above issue, a flux dipping device is proposed, which has a capability of performing a smooth and safe dipping process with a damper structure mounted under a flux tray. Due to the existence of the damper structure, the movement of an electronic component towards the flux tray can be damped to prevent overshooting at the bottom of the tray which could damage the electronic component as well as the tray. Furthermore, since the dipping head can move at a much higher speed when it gets close to the bottom of the flux tray, which reduces a duration of the deceleration action of the dipping head. As a result, an overall efficiency and reliability of the flux dipping process can be improved.

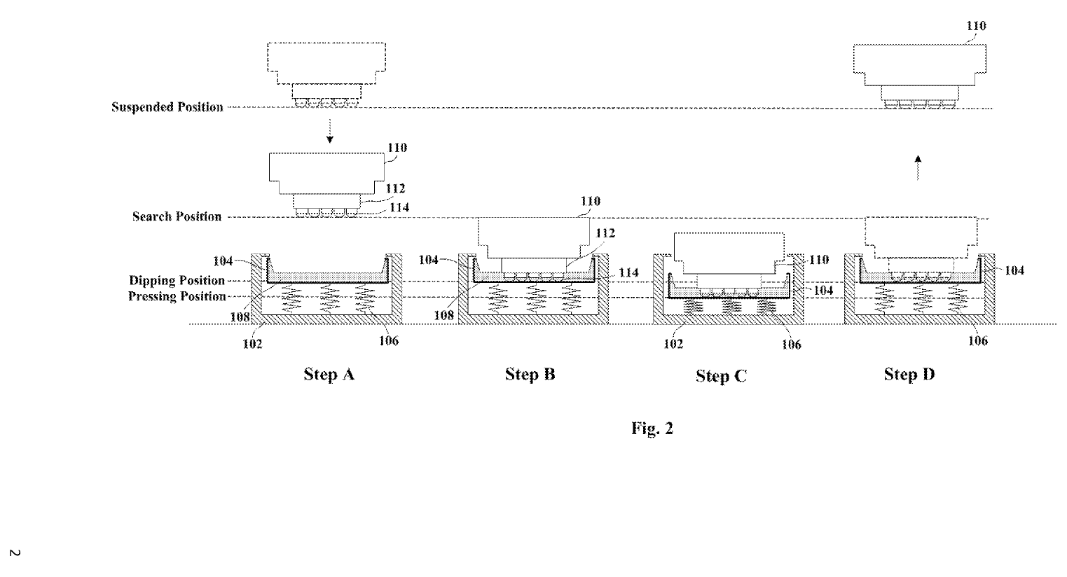

FIG. 2 illustrates a flux dipping method according to an embodiment of the present application. In particular, the flux dipping method can be implemented by a flux dipping device with a damper structure.

As shown in Step A of FIG. 2, the flux dipping device includes a rack 102 such as a frame for mounting a tray 104. The rack 102 may be placed on a platform for the flux dipping process. A flux 108 such as solvents and film-forming agents can be held by the tray 104. In some embodiments, the tray 104 can be made of polytetrafluoroethylene (PTFE) or other suitable materials. A damper 106 is mounted between the rack 102 and the tray 104. For example, the damper 106 may include a set of springs, which may be made of high-strength steel. It is preferred that the set of springs can be evenly distributed between the rack 102 and the tray 104, so that the tray 104 can move generally in a vertical direction when a force is applied downward against the tray 104. In some embodiments, a guide pin or guide rail may be arranged between the tray 104 and the rack 102, which can guide the vertical movement of the tray 104. In some embodiments, the rack 102 may be shaped as a sleeve, while the tray 104 can have a profile generally the same as that of a sidewall of the rack 102, and thus the sidewall of the rack 102 can function to guide the vertical movement of the tray 104.

The flux dipping device further includes a dipping head 110 which can move vertically above the tray 104. An electronic component 112 such as a semiconductor chip can be held by the dipping head 110 and move with the dipping head 110. The electronic component 112 has a soldering material 114 such as solder bumps, which can be dispensed at a bottom side of the electronic component 112. In that case, when the dipping head 110 moves the electronic component 112 to a position close to the tray 104, the electronic component 112, or particularly the soldering material 114 at its bottom side, may be in contact with the flux 108.

Still referring to Step A of FIG. 2, before the flux dipping process starts, the dipping head 110 may be hang in the air, for example, at a suspended position. In some cases, the dipping head 110 may move horizontally with respect to the tray 104 to search for a position which is vertically aligned with the tray 104. A distance between the soldering material 114 and the tray 104 may be around 10 mm to 20 mm, which provides sufficient tolerance for the electronic component 112 during the horizontal movement of the dipping head 110. The dipping head 110 may move at a first speed when it moves from the suspended position to a search position where the dipping head 110 starts to search for the tray 104 for the subsequent dipping. For example, the first speed may be 10 mm/s to 20 mm/s. It can be appreciated that the first speed may be an average speed or a maximum speed for the dipping head 110 when it moves from the suspended position to the search position, or may be a speed when the dipping head 110 reaches the search position. It is not required that the dipping head 110 moves at a constant speed which does not change during that period. It can be appreciated that the dipping head 110 can move much faster than the dipping head 10 shown in Step A of FIG. 1, and thus it can take much less time for the dipping head 110 to reach the search position than the dipping head 10 shown in Step A of FIG. 1. In some embodiments, when the dipping head 110 is at the search position, a distance between the soldering material 114 and the tray 104 may be around 0.2 mm, preferably less than 0.2 mm.

When the dipping head 110 moves past the search position, it may start to decelerate. As shown in Step B of FIG. 2, the dipping head 110 may move from the search position to a dipping position where the soldering material 114 is at least partially immersed in the flux 108 held by the tray 104 and reaches a bottom surface of the tray 104. As such, the tray 104 may be in contact with the soldering material 114 and thus be compressed by the dipping head 110 via the electronic component 112. During the movement from the search position to the dipping position, the dipping head 110 may move at a second speed which is much lower than the first speed at which it moves from the suspended position to the search position. For example, a ratio between the second speed and the first speed is ranging from 5% to 20%. In some embodiments, the speed of the dipping head can be decreased by at most 95% when a distance between the tray 104 and the soldering material 114 is less than 0.03 mm, compared with a maximum speed of the dipping head during its movement from the suspended position to the search position. However, it is not required that the dipping head 110 moves at a speed that is too low, e.g., lower than 0.001 mm/s or even lower, because moving too slow increases the difficulty in control as well as lengthens the time to reach the dipping position. Thus, a duration for the dipping head 110 to reach the dipping position from the search position is not significant, e.g., can be 1 to 2 seconds, or even less.

At the dipping position, a portion or all of the soldering material 114 is immersed in the flux 108, and the dipping head 110 may start to apply a compression force to the tray 104 via the electronic component 112. As such, the tray 104 may start to move downward towards the rack 104. The damper 106 mounted between the rack 102 and the tray 104 can be used to damp the downward movement of the tray 104 when it is compressed downward against the rack 102. It can be appreciated that due to the damping by the damper 106, the speed of the dipping head 110 may further decrease, until it reaches zero at a compressing position as shown in Step C of FIG. 2. As shown in Step C of FIG. 2, the damper 106 which may be a set of springs are compressed further, and a resilient force may be generated. At the same time, a compression force may still be applied by the dipping head 110, which offsets the resilient force of the damper 106. As such, the dipping head 110 may not move, and can have the soldering material 114 maintained in the flux 108 for a period such as 0.5 second to 1 second to have the soldering material 114 fully dipped with the flux 108.

Next, as shown in Step D of FIG. 2, after the soldering material is dipped with certain amount of flux, the dipping head 110 may be moved away from the tray 104, back to the suspended position. Without the compression applied by the dipping head 110, the tray 104 can move upward and back to the dipping position. The damper 106 and the tray 104 can be ready for the next cycle of dipping operation without any residual deformation.

It can be seen that the damper 106 mounted between the rack 102 and the tray 104 can prevent the electronic component 112 from experiencing excessive shock or impact even the dipping head 110 moves at a non-zero speed. In this way, potential damages to the electronic component 112 including the soldering material 114 can be avoided. Furthermore, since it is not required to accurately control the speed of the dipping head 110 when it moves close to the tray 104, the dipping head 110 can decelerate later or closer to the tray 104. In an example, a total process time for one cycle of the flux dipping process according to an embodiment of the present application can be 2.9 seconds, which is much shorter than the process time of 5.8 seconds for the conventional flux dipping process shown in FIG. 1. In this way, the UPH of flux dipping and subsequent compression bonding process can be improved significantly.

In some embodiments, sensors can be installed between the tray 104 and the damper 106 or to the damper 106 to monitor the force applied to the tray 104 in real-time. In this way, the damper 106 can be adjusted accordingly, which allows for dynamic control of the damper 106 response to ensure optimal protection of the electronic component 112 during the flux dipping process.

In some embodiments, the set of springs of the damper 106 may be operable between a pre-pressed state and a pressed state. When the dipping head 110 is not in contact with the tray 104 and does not apply a force to the tray 104, the set of springs may be operating in the pre-pressed state. For example, a predetermined compression force ranging from 5N to 20N, which preferably is 5N, may be applied to the set of springs. Furthermore, when the tray 104 is compressed by the dipping head 110 at the compressing position, for example, the set of springs may be operating in the pressed state. Accordingly, the set of springs may switch from the pre-pressed state to the pressed state in response to the downward movement of the tray 104 from the dipping position to the compressing position. It is noted that the pre-pressing to the set of springs can mitigate force overshooting for the dipping head. More specifically, if the set of springs are not pre-compressed, the dipping head 110 may have to travel a greater distance from the search position to the compressing position. This longer travel distance means that the set of springs may be compressed for a relatively long time, which can lead to a higher risk of force overshooting due to the inertia and momentum of the movement of the dipping head 110. In contrast, pre-compressing the set of springs can reduce the total travel distance required for the set of springs to reach the compressing position. The shorter travel distance allows for more precise control, as the system has less distance to cover and less time to build up excess momentum, which helps to minimize the risk of force overshooting.

Although in the embodiment shown in FIG. 2 the damper 106 is a set of springs, in some other embodiments, the damper 106 can include one or more voice coil motors (VCM) or one or more air bearings, or any other suitable damping mechanism.

The discussion herein includes numerous illustrative figures that show various portions of a flux dipping device and a flux dipping method implemented by the same. For illustrative clarity, such figures do not show all aspects of each exemplary method. Any of the example methods provided herein may share any or all characteristics with any or all other methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A flux dipping device, comprising:
a rack,
a tray mounted on the rack and configured to hold flux; and
a damper mounted between the rack and the tray, and configured to damp a downward movement of the tray when the tray is compressed downward against the rack.

2. The flux dipping device of claim 1, wherein the damper comprises a set of springs operable between a pre-pressed state and a pressed state, and wherein the set of springs are operable to switch from the pre-pressed state to the pressed state in response to the downward movement of the tray when the tray is compressed downward against the rack, and in the pre-pressed state the set of springs are pressed with a predetermined compression force.

3. The flux dipping device of claim 2, further comprising:
a dipping head for holding an electronic component with a soldering material dispensed at its bottom side, wherein the dipping head is configured to move between a suspended position and a compressing position, and during a movement of the dipping head from the suspended position to the compressing position, the dipping head compresses the tray against the rack till the damper reaches the pressed state.

4. The flux dipping device of claim 3, wherein the dipping head is configured to move at a first speed during a first period of its movement from the suspended position to the compressing position, and at a second speed during a second period of its movement from the suspended position to the compressing position, and wherein a ratio between the second speed and the first speed is ranging from 5% to 20%, and a distance between the tray and the soldering material is less than 0.2 mm when the tray moves at the second speed.

5. The flux dipping device of claim 3, wherein the dipping head is configured to decrease its speed during its downward movement to the tray, and a speed of the dipping head is decreased by at most 95% when a distance between the tray and the soldering material is 0.03 mm.

6. The flux dipping device of claim 2, wherein the predetermined compression force ranges from 5 N to 20 N.

7. The flux dipping device of claim 1, wherein the damper comprises a voice coil motor (VCM) or an air bearing.

8. The flux dipping device of claim 7, wherein the damper is initially in a relaxed state when it comprises a voice coil motor (VCM) or an air bearing.

9. A flux dipping method, comprising:
providing a tray holding flux mounted on a rack via a damper;
moving downward towards the tray a dipping head holding an electronic component with a soldering material dispensed at its bottom side;
compressing by the dipping head the tray against the rack via the damper to dip the soldering material with the flux in the tray; and
moving the dipping head away from the tray.

10. The flux dipping method of claim 9, wherein the damper comprises a set of springs operable between a pre-pressed state at which the set of springs are pressed with a predetermined compression force and a pressed state at which the set of springs are further pressed, and compressing by the dipping head the tray against the rack via the damper further comprises:
compressing the set of springs from the pre-pressed state to the pressed state.

11. The flux dipping method of claim 9, wherein moving downward towards the tray a dipping head further comprises:
moving the dipping head at a first speed at a first period; and
moving the dipping head at a second speed at a second period after the first period and when a distance between the tray and the soldering material is less than 0.2 mm, wherein a ratio between the second speed and the first speed is ranging from 5% to 20%.

12. The flux dipping method of claim 9, wherein moving downward towards the tray a dipping head further comprises:
decreasing, during the downward of dipping head, a speed of the dipping head by at most 95% when a distance between the tray and the soldering material is 0.03 mm.

13. The flux dipping method of claim 10, wherein the predetermined compression force ranges from 5 N to 20 N.
